(19) United States
(12) Patent Application Publication
(10) Pub. No.: US 2018/0136985 A1
(43) Pub. Date: May 17, 2018

(54) ASSET PLACEMENT MANAGEMENT IN A SHARED POOL OF CONFIGURABLE COMPUTING RESOURCES

(71) Applicant: International Business Machines Corporation, Armonk, NY (US)

(72) Inventors: Venkatesh Sainath, Bangalore (IN); Amit J. Tendolkar, Bangalore (IN)

(21) Appl. No.: 15/355,025

(22) Filed: Nov. 17, 2016

(51) Int. Cl. G06F 9/50; H05K 7/20; G06F 1/20; G06F 9/48

(52) U.S. Cl. CPC G06F 9/5094; H05K 7/20718; G06F 2209/5011; G06F 9/4856; G06F 1/206

(57) ABSTRACT

Disclosed aspects relate to asset placement management in a shared pool of configurable computing resources having both a plurality of physical servers and a plurality of physical cooling fans. A set of relationships may be identified with respect to the plurality of physical cooling fans. In response to identifying the set of relationships, a placement arrangement may be determined for a set of assets with respect to the plurality of physical servers. The set of assets may be deployed based on the placement arrangement.

### BACKGROUND

This disclosure relates generally to computer systems and, more particularly, relates to asset placement management in a shared pool of configurable computing resources. The amount of data that needs to be managed in cloud-like environments which use a plurality of physical servers and a plurality of physical cooling fans is increasing. Data management may be desired to be performed as efficiently as possible. As data needing to be managed increases, the need for asset placement management in a shared pool of configurable computing resources may increase.

### SUMMARY

Aspects of the disclosure relate to asset placement management in a shared pool of configurable computing resources having both a plurality of physical servers and a plurality of physical cooling fans. A cooling fan configuration with respect to a server environment may be determined. The cooling fan configuration may indicate which servers are cooled by which cooling fans. Based on the cooling fan configuration, a placement arrangement for a set of assets may be determined. For instance, assets may be placed on servers that are associated with active workload/cooling fan configurations to avoid the need to activate additional cooling fans. Assets may be migrated from particular servers to other servers based on server temperature and fan utilization information. Candidate server arrangements may be recommended to make use of cooling fans already in operation within a server chassis. Asset deployments may be performed to take advantage of the cooling fan configuration of the server environment.

Disclosed aspects relate to asset placement management in a shared pool of configurable computing resources having both a plurality of physical servers and a plurality of physical cooling fans. A set of relationships may be identified with respect to the plurality of physical servers and the plurality of physical cooling fans. A first physical cooling fan may be configured and arranged to cool a first group of physical serves. A second physical cooling fan may be configured and arranged to cool a second group of physical servers. A placement arrangement for a set of assets with respect to the plurality of physical servers may be determined. The placement arrangement may be determined based on the set of relationships. The set of assets may be deployed. This deployment may be based on the placement arrangement.

The above summary is not intended to describe each illustrated embodiment or every implementation of the present disclosure.

### BRIEF DESCRIPTION OF THE SEVERAL VIEWS OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts a cloud computing node according to embodiments.

FIG. 2 depicts a cloud computing environment according to embodiments.

FIG. 3 depicts abstraction model layers according to embodiments.

FIG. 4 is a flowchart illustrating a method for asset placement management in a shared pool of configurable computing resources having both a plurality of physical servers and a plurality of physical cooling fans, according to embodiments.

FIG. 5 shows an example system for asset placement management in a shared pool of configurable computing resources having both a plurality of physical servers and a plurality of physical cooling fans, according to embodiments.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the disclosure relate to asset placement management in a shared pool of configurable computing resources having both a plurality of physical servers and a plurality of physical cooling fans. A cooling fan configuration with respect to a server environment may be determined. The cooling fan configuration may indicate which servers are cooled by which cooling fans. Based on the cooling fan configuration, a placement arrangement for a set of assets may be determined. For instance, assets may be placed on servers that are associated with active workload/cooling fan configurations to avoid the need to activate additional cooling fans. Assets may be migrated from particular servers to other servers based on server temperature and fan utilization information. Candidate server arrangements may be recommended to make use of cooling fans already in operation within a server chassis. Asset deployments may be performed to take advantage of the cooling fan configuration of the server environment. Leveraging cooling fan arrangement/configuration information for asset deployment may be associated with power consumption efficiency, asset performance, and component longevity.

In server chassis, cooling fans are one component used to facilitate heat dissipation of servers and other hardware components. In some situations, multiple servers may be configured to be cooled by a single cooling fan. For instance, a single cooling fan may be used to provide cooling to two separate physical servers. Aspects of the disclosure relate to the recognition that, in some situations, assets (e.g., virtual machines, workloads, application programs, logical partitions) are deployed to servers without taking into account the cooling fan configuration of the chassis, leading to challenges related to providing sufficient server cooling and maintaining asset performance. Accordingly, aspects of the disclosure relate to identifying a set of relationships between physical servers and physical cooling fans, and using these server-cooling fan relationships to determine a placement for a set of assets with respect to the physical servers. In this way, assets may be deployed to a group of physical servers such that the cooling fan configuration of the server chassis may be leveraged for thermal management efficiency.

Aspects of the disclosure include a method, system, and computer program product for asset placement management in a shared pool of configurable computing resources having both a plurality of physical servers and a plurality of physical cooling fans. A set of relationships may be identified with respect to the plurality of physical servers and the plurality of physical cooling fans. This set of relationships may indicate a first physical cooling fan configured and arranged to cool a first group of physical servers. This set of relationships may also indicate a second physical cooling fan configured and arranged to cool a second group of physical servers. A placement arrangement may be determined for a set of assets with respect to the plurality of physical servers. This placement arrangement may be determined based on the set of relationships. A set of assets may be deployed based on the placement arrangement. Altogether, aspects of the disclosure can have performance or efficiency benefits (e.g., wear-rate, service-length, reliability, speed, flexibility, load balancing, responsiveness, stability, high availability, resource usage, productivity). Aspects may save resources such as bandwidth, disk, processing, or memory.

It is understood in advance that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for loadbalancing between clouds).

A cloud computing environment is service oriented with a focus on statelessness, low coupling, modularity, and semantic interoperability. At the heart of cloud computing is an infrastructure comprising a network of interconnected nodes.

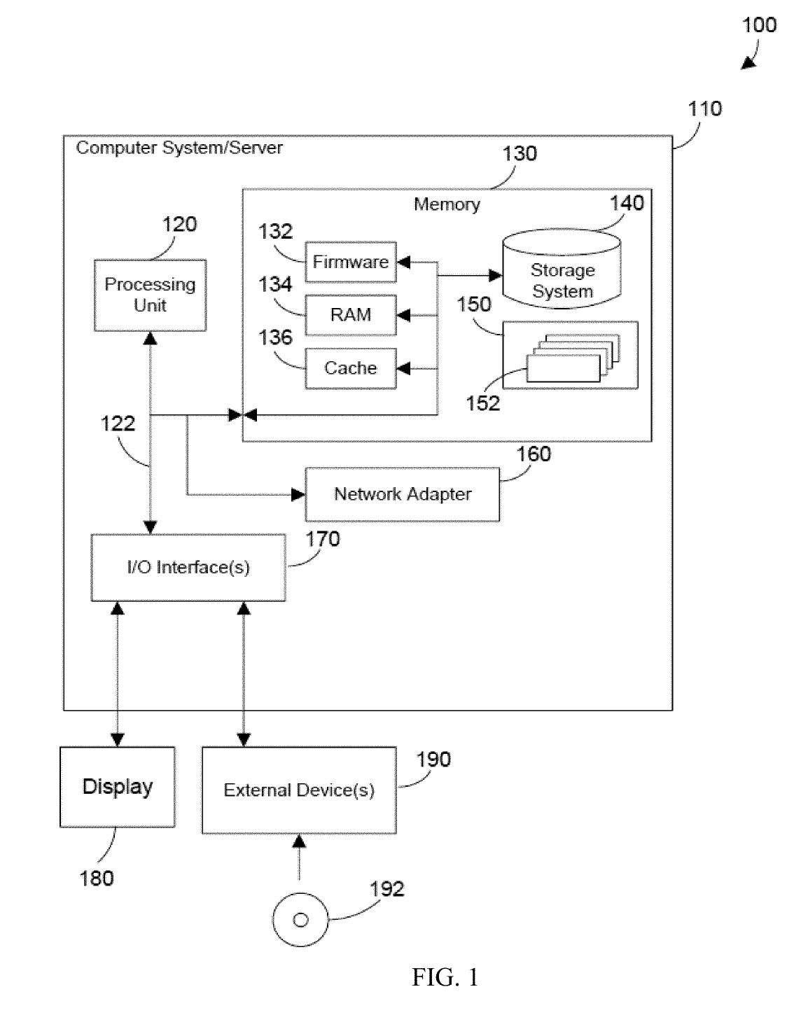

Referring now to FIG. 1, a block diagram of an example of a cloud computing node is shown. Cloud computing node 100 is only one example of a suitable cloud computing node and is not intended to suggest any limitation as to the scope of use or functionality of embodiments of the invention described herein. Regardless, cloud computing node 100 is capable of being implemented and/or performing any of the functionality set forth hereinabove.

In cloud computing node 100 there is a computer system/server 110, which is operational with numerous other general purpose or special purpose computing system environments or configurations. Examples of well-known computing systems, environments, and/or configurations that may be suitable for use with computer system/server 110 include, but are not limited to, personal computer systems, server computer systems, tablet computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 110 may be described in the general context of computer system executable instructions, such as program modules, being executed by a computer system. Generally, program modules may include routines, programs, objects, components, logic, data structures, and so on that perform particular tasks or implement particular abstract data types. Computer system/server 110 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 1, computer system/server 110 in cloud computing node 100 is shown in the form of a general-purpose computing device. The components of computer system/server 110 may include, but are not limited to, one or more processors or processing units 120, a system memory 130, and a bus 122 that couples various system components including system memory 130 to processing unit 120.

Bus 122 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

Computer system/server 110 typically includes a variety of computer system readable media. Such media may be any available media that is accessible by computer system/server 110, and it includes both volatile and non-volatile media, removable and non-removable media. An example of removable media is shown in FIG. 1 to include a Digital Video Disc (DVD) 192.

System memory 130 can include computer system readable media in the form of volatile or non-volatile memory, such as firmware 132. Firmware 132 provides an interface to the hardware of computer system/server 110. System memory 130 can also include computer system readable media in the form of volatile memory, such as random access memory (RAM) 134 and/or cache memory 136. Computer system/server 110 may further include other removable/non-removable, volatile/non-volatile computer system storage media. By way of example only, storage system 140 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 122 by one or more data media interfaces. As will be further depicted and described below, memory 130 may include at least one program product having a set (e.g., at least one) of program modules that are configured to carry out the functions described in more detail below.

Program/utility 150, having a set (at least one) of program modules 152, may be stored in memory 130 by way of example, and not limitation, as well as an operating system, one or more application programs, other program modules, and program data. Each of the operating system, one or more application programs, other program modules, and program data or some combination thereof, may include an implementation of a networking environment. Program modules 152 generally carry out the functions and/or methodologies of embodiments of the invention as described herein.

Computer system/server 110 may also communicate with one or more external devices 190 such as a keyboard, a pointing device, a display 180, a disk drive, etc.; one or more devices that enable a user to interact with computer system/server 110; and/or any devices (e.g., network card, modem, etc.) that enable computer system/server 110 to communicate with one or more other computing devices. Such communication can occur via Input/Output (I/O) interfaces 170. Still yet, computer system/server 110 can communicate with one or more networks such as a local area network (LAN), a general wide area network (WAN), and/or a public network (e.g., the Internet) via network adapter 160. As depicted, network adapter 160 communicates with the other components of computer system/server 110 via bus 122. It should be understood that although not shown, other hardware and/or software components could be used in conjunction with computer system/server 110. Examples, include, but are not limited to: microcode, device drivers, redundant processing units, external disk drive arrays, Redundant Array of Independent Disk (RAID) systems, tape drives, data archival storage systems, etc.

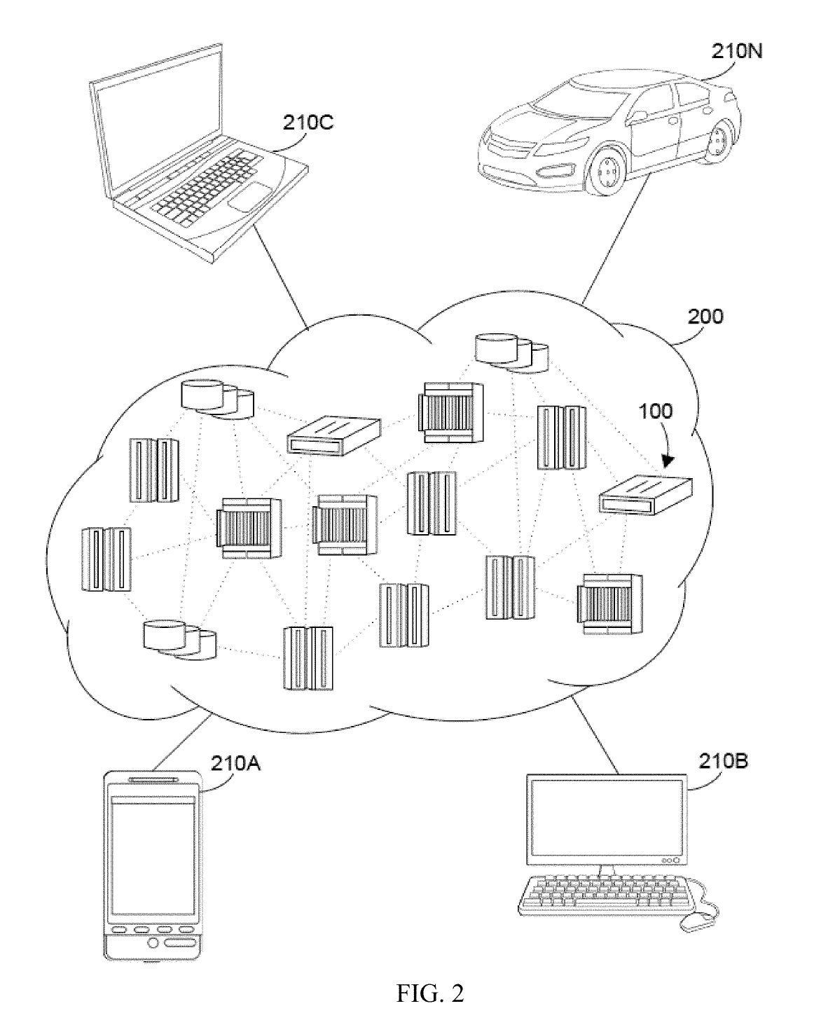

Referring now to FIG. 2, illustrative cloud computing environment 200 is depicted. As shown, cloud computing environment 200 comprises one or more cloud computing nodes 100 with which local computing devices used by cloud consumers, such as, for example, personal digital assistant (PDA) or cellular telephone 210A, desktop computer 210B, laptop computer 210C, and/or automobile computer system 210N may communicate. Nodes 100 may communicate with one another. They may be grouped (not shown) physically or virtually, in one or more networks, such as Private, Community, Public, or Hybrid clouds as described hereinabove, or a combination thereof. This allows cloud computing environment 200 to offer infrastructure, platforms and/or software as services for which a cloud consumer does not need to maintain resources on a local computing device. It is understood that the types of computing devices 210A-N shown in FIG. 2 are intended to be illustrative only and that computing nodes 100 and cloud computing environment 200 can communicate with any type of computerized device over any type of network and/or network addressable connection (e.g., using a web browser).

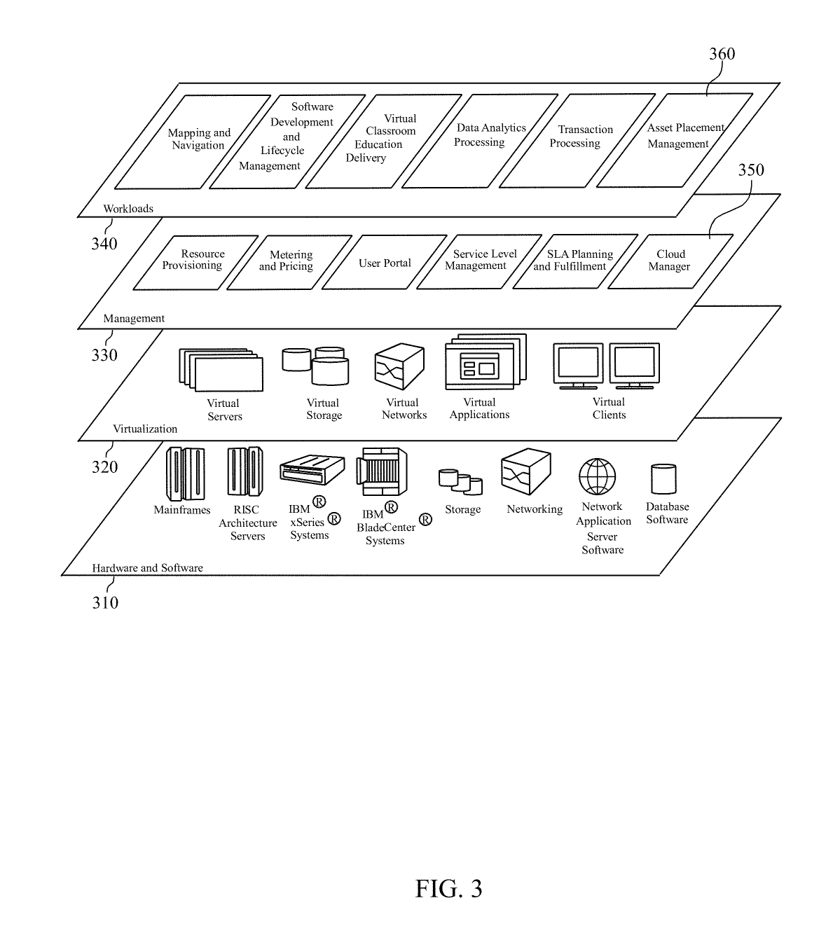

Referring now to FIG. 3, a set of functional abstraction layers provided by cloud computing environment 200 in FIG. 2 is shown. It should be understood in advance that the components, layers, and functions shown in FIG. 3 are intended to be illustrative only and the disclosure and claims are not limited thereto. As depicted, the following layers and corresponding functions are provided.

Hardware and software layer 310 includes hardware and software components. Examples of hardware components include mainframes, in one example IBM System z systems; RISC (Reduced Instruction Set Computer) architecture based servers, in one example IBM System p systems; IBM System x systems; IBM BladeCenter systems; storage devices; networks and networking components. Examples of software components include network application server software, in one example IBM Web Sphere® application server software; and database software, in one example IBM DB2® database software. IBM, System z, System p, System x, BladeCenter, WebSphere, and DB2 are trademarks of International Business Machines Corporation registered in many jurisdictions worldwide.

Virtualization layer 320 provides an abstraction layer from which the following examples of virtual entities may be provided: virtual servers; virtual storage; virtual networks, including virtual private networks; virtual applications and operating systems; and virtual clients.

In one example, management layer 330 may provide the functions described below. Resource provisioning provides dynamic procurement of computing resources and other resources that are utilized to perform tasks within the cloud computing environment. Metering and Pricing provide cost tracking as resources are utilized within the cloud computing environment, and billing or invoicing for consumption of these resources. In one example, these resources may comprise application software licenses. Security provides identity verification for cloud consumers and tasks, as well as protection for data and other resources. User portal provides access to the cloud computing environment for consumers and system administrators. Service level management provides cloud computing resource allocation and management such that required service levels are met. Service Level Agreement (SLA) planning and fulfillment provide pre-arrangement for, and procurement of, cloud computing resources for which a future requirement is anticipated in accordance with an SLA. A cloud manager 350 is representative of a cloud manager (or shared pool manager) as described in more detail below. While the cloud manager 350 is shown in FIG. 3 to reside in the management layer 330, cloud manager 350 can span all of the levels shown in FIG. 3, as discussed below.

Workloads layer 340 provides examples of functionality for which the cloud computing environment may be utilized. Examples of workloads and functions which may be provided from this layer include: mapping and navigation; software development and lifecycle management; virtual classroom education delivery; data analytics processing; transaction processing; and asset placement management 360, which may be utilized as discussed in more detail below.

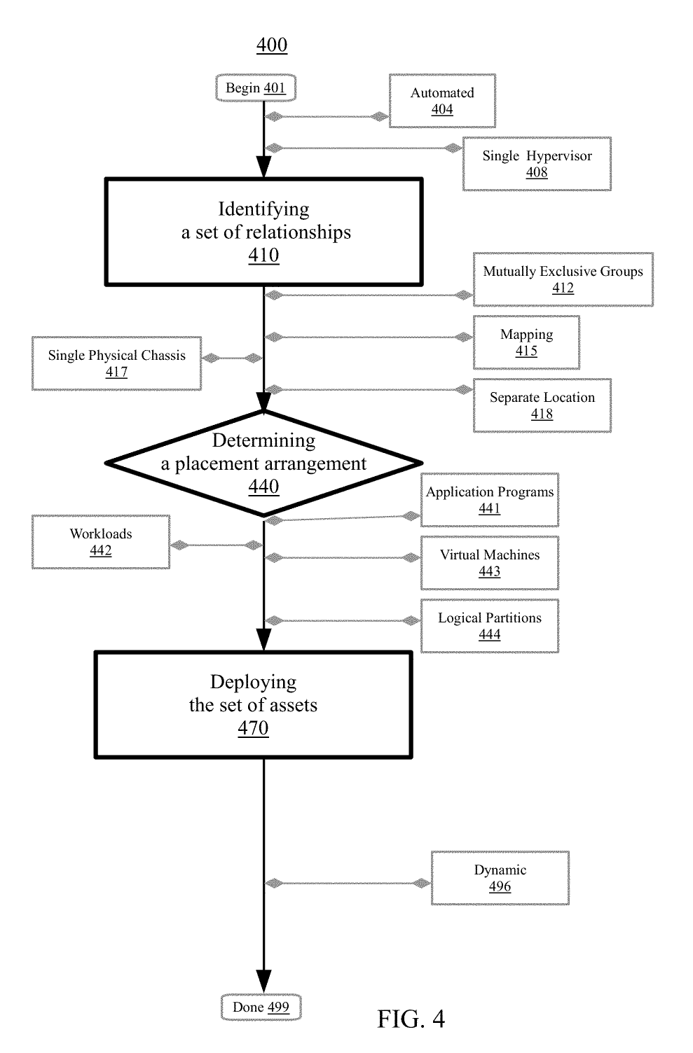

FIG. 4 is a flowchart illustrating a method 400 for asset placement management in a shared pool of configurable computing resources having both a plurality of physical servers and a plurality of physical cooling fans. Aspects of FIG. 4 relate to using a set of relationships between a plurality of physical servers and a plurality of physical cooling fans to determine a placement arrangement for a set of assets, and deploy the set of assets based on the placement arrangement. Generally, the plurality of physical servers (also referred to herein as “physical servers” or just “servers) may include computing devices or physical network nodes configured to provide functionality for other programs or devices (e.g., clients). The plurality of physical servers may be configured to provide various services such as data/resource sharing functionality, computation operations, data storage/streaming functionality, or the like to one or more clients. As examples, the plurality of physical servers may include one or more database servers, file servers, mail servers, print servers, web servers, game servers, collaboration servers, application servers, and the like. In embodiments, the plurality of physical servers may be configured to host a set of assets. The set of assets may include one or more application programs, workloads, virtual machines, or logical partitions. In embodiments, the plurality of physical servers may be associated with a set of physical cooling fans. The plurality of physical cooling fans (also referred to herein as “cooling fans” or just “fans”) may include fans configured to dissipate heat generated by operation of the plurality of physical servers via active cooling techniques. In embodiments, a single physical cooling fan may be configured to provide cooling to one or more physical servers (e.g., multiple servers may share the same cooling fans). In embodiments, the plurality of physical cooling fans may be stationed in the chassis of a server rack maintaining the physical servers. Other types of physical servers and physical cooling fans are also possible. The method 400 may begin at block 401.

In embodiments, the identifying, determining, deploying, and other steps described herein may each occur in an automated fashion without user intervention at block 404. In embodiments, the identifying, determining, deploying, and other steps described herein may be carried out by an internal asset placement management module maintained in a persistent storage device of the shared pool of configurable computing resources. In certain embodiments, the identifying, determining, deploying, and other steps described herein may be carried out by an external asset placement management module hosted by a remote computing device or server (e.g., accessible via a subscription, usage-based, or other service model). In this way, aspects of asset placement management may be performed using automated computing machinery without manual action. Other methods of performing the steps described herein are also possible.

In embodiments, a single hypervisor may manage the plurality of physical servers at block 408. Generally, the hypervisor may include a piece of computer software (e.g., program, application, firmware, module) or computer hardware to create and manage virtual machines. The hypervisor may be configured to create a number of virtual machines each having different operating systems and virtual operating platforms for managing deployed assets and workloads. In embodiments, aspects of the disclosure relate to using a single hypervisor to manage a plurality of physical servers. For instance, a single central hypervisor maintained in a chassis management module of a server chassis may create multiple instances of a variety of operating systems which share the virtualized hardware resources of the plurality of physical servers. The hypervisor may monitor the deployed assets, workload activity, resource utilization, and cooling configuration of each server of the set of physical servers, and make resource allocation and asset deployment decisions to provide each operating system the resources it needs to manage hosted workloads. In embodiments, a single hypervisor may be configured to manage a portion of the servers of a server chassis. For example, the plurality of physical servers may include four distinct symmetric multiprocessor (SMP) systems, each SMP system managed by a separate hypervisor. Other methods of using a hypervisor to manage the plurality of physical servers are also possible.

At block 410, a set of relationships with respect to the plurality of physical servers and the plurality of physical cooling fans is identified. This set of relationships may indicate a first physical cooling fan. This first cooling fan is configured and arranged to cool a first group of physical servers. This set of relationships may also indicate a second physical cooling fan. This second cooling fan is configured and arranged to cool a second group of physical servers. Generally, identifying can include detecting, recognizing, discovering, sensing, or otherwise ascertaining the set of relationships. The set of relationships may indicate the physical location of the plurality of physical cooling fans with respect to the plurality of physical servers. For instance, the set of relationships may indicate which cooling fans are being utilizing to provide cooling to which servers of a server chassis. As an example, as described herein, the set of relationships may indicate that a first cooling fan is configured to provide cooling to a first group of physical servers, and that a second cooling fan is configured to provide cooling to a second group of physical servers. In embodiments, identifying may include using a set of service processors associated with the plurality of physical servers to detect the physical location (e.g., server slot) of one or more servers within a server chassis, and ascertain which cooling fans correspond to the physical locations of the physical servers. Other methods of identifying the set of relationships with respect to the plurality of physical servers and the plurality of physical cooling fans are also possible.

In embodiments, the first and second groups of physical servers may be mutually exclusive at block 412. Generally, mutually exclusive may indicate that the first and second groups of physical servers are physically separate, distinct, isolated, disconnected, or otherwise independent of one another. In embodiments, the physical servers of the first group may not overlap with the physical servers of the second group. For instance, the first and second groups may each include wholly independent servers, such that no server is a member of both the first and second groups of physical servers (e.g., simultaneously). In embodiments, the first and second groups of physical servers may not share cooling fans. For instance, both the first and second groups of physical servers may be assigned separate (e.g., unique) groups of cooling fans to provide heat dissipation. As an example, a first group of physical servers having 4 servers may be assigned two cooling fans A and B to provide cooling for the first group (e.g., each cooling fan provides cooling to two servers), and a second group of physical servers having 4 servers may be assigned two cooling fans C and D to provide cooling for the second group. In certain embodiments, the first and second groups of physical servers may be managed by separate hypervisors. In this way, the first and second groups of physical servers may be physically and logically independent of one another, and be cooled by different cooling fans. Other types of mutual exclusivity between the first and second groups of physical servers are also possible.

In embodiments, the physical cooling fans may be mapped at block 415. The first physical cooling fan may be configured and arranged to cool the first group of physical servers. The second physical cooling fan may be configured and arranged to cool the second group of physical servers. Generally, mapping may include associating, linking, connecting, aligning, coupling, relating, or otherwise corresponding the physical cooling fans with the first group of physical servers. In embodiments, mapping may include ascertaining (e.g., based on the set of relationships) which physical cooling fans are arranged to cool which physical servers, and generating an indication of the correspondence between the physical servers and associated cooling fans. In embodiments, mapping may include creating (e.g., establishing, generating, formulating, deriving) a physical and logical topology map to represent which physical cooling fans correspond to (e.g., are configured to cool) which physical servers. For instance, as described herein, the physical and logical topology map may indicate that the first group of physical servers is configured to be cooled by the first physical cooling fan, and that the second group of physical servers is configured to be cooled by the second physical cooling fan. In embodiments, the physical and logical topology map may be maintained by a chassis management module configured to manage the plurality of physical servers and the plurality of physical cooling fans within a server environment.

Consider the following example. A server chassis may include 6 servers arranged in two vertical columns, with three servers per column. Servers A, B, and C may be located in a first column in server slots 1, 2, and 3, respectively, and Servers D, E, and F may be located in a second column in server slots 4, 5, and 6, respectively. As described herein, a set of service processors (e.g., one service processor in each server) may be configured to detect the server slots that house each server. The set of service processors may send a server location report to a chassis management module indicating the physical location (e.g., server slot) for each server. As an example, the set of service processors may indicate that Server A is in server slot 1, Server D is in slot 4, Server F is in slot 6, and the like. The chassis management module may aggregate the server location reports from each service processor, and correlate the physical location of each server with the physical location of each cooling fan to generate a physical and logical topology map indicating which servers are configured to be cooled by which cooling fans (e.g., a first cooling fan is configured to cool server slots 1 and 2, a fourth cooling fan is configured to cool server slots 5 and 6). As an example, the physical and logical topology map may indicate that Servers A and B are cooled by a first cooling fan (e.g., fan configured to cool the servers in server slots 1 and 2), Servers B and C are cooled by a second cooling fan (e.g., fan configured to cool the servers in slots 2 and 3), Servers D and E are cooled by a third cooling fan (e.g., fan configured to cool the servers in slots 4 and 5), and Servers E and F are cooled by a fourth cooling fan (e.g., fan configured to cool the servers in slots 5 and 6). Other methods of mapping physical servers with physical cooling fans are also possible.

In embodiments, the plurality of physical servers may be embedded in a single physical chassis at block 417. The physical chassis may include a structure configured to house or physically maintain servers in various different physical and logical configurations. The physical chassis may include one or more servers configured in parallel to collaborate on a single workload. As examples, the physical chassis may include a rack structure, a pedestal (tower) structure, a blade structure, or other type of physical form factor. The physical chassis may include a number of volumes and physical dimensions. As examples, the physical chassis may include one or more of 1 U, 2 U, 14 U, 20 U, or other physical classifications (e.g., where “U” indicates the number of units or servers housed by the chassis). As described herein, the plurality of physical servers may be embedded in a single physical chassis. For example, multiple groups of physical servers (e.g., first and second group of servers) may be housed in the same physical chassis. In certain embodiments, a single physical chassis may house a plurality of servers configured in multiple logical groupings. The physical chassis may support a variety of physical server arrangements. As examples, the physical chassis may support 14 physical servers arranged in 2 vertical columns of 7, 16 physical servers arranged in four blocks of 4, or the like. Other physical server arrangements using a single physical chassis are also possible.

In embodiments, the plurality of physical servers and physical cooling fans may be located in separate geographic locations at block 418. The first group of physical servers and the first physical cooling fan may be located in a first geographic location. The second group of physical servers and the second physical cooling fan may be located in a second geographic location. A threshold distance may separate the first and second geographic locations. The separate geographic locations may include different rooms in the same building, different data centers, different server chassis in the same data center, different towns, states, provinces, prefectures, countries, continents, or the like. As described herein, the first group of physical servers and the first cooling fan may be located in a first geographic location, and the second group of physical servers and the second physical cooling fan may be located in a second geographic location. As an example, the first group of physical servers and the first cooling fan may be located in Germany, and the second group of physical servers and the second cooling fan may be located in Ontario, Canada. In embodiments, the first and second geographic locations may be separated by a threshold distance. The threshold distance may be a designated benchmark length, radius, or separation between the first and second geographic locations. As an example, the threshold distance may be 3 feet, 40 miles, 500 kilometers, or other specified distance. In embodiments, the first and second groups of physical servers may belong to the same distributed networking environment or cloud network. Other geographic arrangements for the physical servers and the physical cooling fans are also possible.

At block 440, a placement arrangement is determined for a set of assets with respect to the plurality of physical servers. The placement arrangement may be determined based on the set of relationships previously established. Generally, determining can include formulating, deriving, computing, identifying, resolving, or otherwise ascertaining the placement arrangement for the set of assets with respect to the plurality of physical servers. The placement arrangement may include a configuration for deployment of various assets (e.g., workloads, application programs, logical partitions, virtual machines) to particular physical servers of the plurality of physical servers. For instance, the placement arrangement may indicate a recommendation of which assets should be allocated to which physical servers. As described herein, the placement arrangement may be determined based on the set of relationships. In embodiments, determining may include analyzing (e.g., examining, assessing) the level of operation (e.g., revolutions per minute, voltage) of a set of cooling fans with respect to the activity (e.g., workload intensity, temperature) of the physical servers to which they correspond, and ascertaining a host server for the set of assets that is associated with stable temperatures (e.g., temperatures below a threshold, temperature fluctuation below a threshold), cooling fan power efficiency (e.g., cooling fan voltage below a power threshold), and logical/resource compatibility (e.g., sufficient computing resources, appropriate logical group/hypervisor), and other factors. For instance, example placement arrangements may prioritize allocation of the set of assets to servers that are associated with active fans (e.g., to avoid the need to turn on additional fans), servers that are associated with low temperatures relative to their workload intensity, or servers that are adjacent to other active servers (e.g., to leverage cooling from shared fans). Other methods of determining a placement arrangement for the set of assets with respect to the plurality of physical servers are also possible.

In embodiments, the set of assets may be selected from a group. The set of assets may include one or more application programs at block 441. Generally, an application program may include a form of computer software configured to perform a specific task or function. In embodiments, the application program may include an application programming interface (e.g., set of subroutine definitions and protocols for building software and applications). In certain embodiments, the application program may include an executable program file. As examples, the application program may include database programs, image editing software, enterprise management applications, development tools, web browsers, communication programs, and other types of software. The set of assets may include one or more workloads at block 442. Generally, a workload can include a collection of tasks, processes, or services scheduled for management by a particular physical server. As examples, workloads can include batch workloads (e.g., data volumes for processing), transactional workloads (e.g., billing and ordering tasks), analytic workloads (e.g., holistic data examination), high performance workloads (e.g., complex, specialized processing assignments), database workloads (e.g., data retrieval, calculation operations), or the like. The set of assets may include one or more virtual machines at block 443. Generally, a virtual machine may include an operating system or application environment configured to emulate particular dedicated hardware. The virtual machine may be configured to access system resources (e.g., of a connected host server) and be managed by a hypervisor (e.g., single hypervisor configured to manage the physical servers). As examples, virtual machines may include system virtual machines, process virtual machines, virtual machines for data/operating system configuration backup, software testing, workload migration, workload consolidation, fault tolerance, or the like. The set of assets may include one or more logical partitions at block 444. Generally, a logical partition may include a subset of a computer's hardware resources virtualized as a separate computer (e.g., a single physical machine, such as a server, can be partitioned into multiple logical partitions, each hosting a separate operating system). In embodiments, logical partitions may be used for creating separate operating system instances for database operations, client/server operations, test and production environment separation, or the like. Other types of assets are also possible.

At block 470, the set of assets may be deployed. The deployment may be based on the placement arrangement. Generally, deploying can include assigning, placing, apportioning, designating, distributing, transferring, or otherwise allocating the set of assets. As described herein, aspects of the disclosure relate to the recognition that deploying assets to a plurality of physical servers based on the relationship between the physical servers and a plurality of physical cooling fans may be associated with power consumption efficiency, asset performance, and component longevity. Accordingly, aspects of the disclosure relate to deploying the set of assets based on the placement arrangement. In embodiments, deploying may include migrating an asset from a first physical server to a second server based on the placement arrangement. In embodiments, deploying may include utilizing the hypervisor to install an asset on a particular physical server as indicated by the placement arrangement. As an example, the hypervisor may parse the placement arrangement, and identify that a first physical server is physically adjacent to other active servers (e.g., physical servers having other assets/workloads), such that it may be implicitly cooled by the cooling fans for those servers. Accordingly, the hypervisor may configure the first server for receiving deployment of an asset. For instance, the hypervisor may partition storage space of the first physical server to maintain a particular asset, configure the operating system parameters to accommodate the particular asset, and allocate resources of the first physical server for use by the particular asset. In response to configuring the first physical server, the particular asset may be transferred to and established on the first physical server by the hypervisor. Other methods of deploying the set of assets based on the placement arrangement are also possible.

Consider the following example. A server chassis may include 16 physical servers arranged in two vertical columns A and B, such that each vertical column includes two groups of 4 servers each. Each server may be associated with a server identifier consisting of the letter of the column in which it is placed (e.g., A or B), and a number indicating the position of the server in the server chassis with respect to the top server (e.g., the server in the fourth slot from the top in column A is associated with a server identifier of A4, the server in the sixth slot from the top in column B is associated with a server identifier of B6). The server chassis may include 8 cooling fans, such that each cooling fan is configured to provide cooling to two physical servers. In embodiments, as described herein, a set of service processors (e.g., one service processor in each server) may be configured to detect the placement of each physical server in the chassis, and send a server location report to a chassis management module. The chassis management module may aggregate the server location reports for each physical server, and identify a set of relationships between the plurality of physical servers and the plurality of cooling fans (e.g., ascertain which cooling fans correspond to which physical servers.) Based on the set of relationships, a placement arrangement for a set of assets may be determined. For instance, the chassis management module may monitor the thermal profile for each physical server, the asset/workload configuration for each server, and the level of operation of each cooling fan of the server chassis. In certain embodiments, a thermal efficiency index value indicating the temperature of a server with respect to the fan voltage of the cooling fan(s) corresponding to that server may be computed and used to determine the placement arrangement. As an example, consider a situation in which servers A1, A3, A4, A7, B2, and B9 are hosting active workloads, and are associated with active cooling fans. The chassis management module may analyze the thermal profiles for each server, as well as the active fans in the server chassis, and determine that server A2 has a thermal efficiency index value above a threshold (e.g., server A2 may benefit from the cooling of cooling fans for servers A1 and A3, resulting in a high thermal efficiency index value). For instance, the server A2 may have a thermal efficiency index value of 84, achieving a thermal efficiency index threshold of 70. Accordingly, as described herein, the set of assets may be placed based on the placement arrangement. For instance, the hypervisor may be configured to install the set of assets on server A2. Other methods of asset placement management based on the relationship between a plurality of physical servers and a plurality of physical cooling fans are also possible.

In embodiments, the identifying, determining, and the deploying, and other steps described herein may each occur in a dynamic fashion to streamline asset placement management at block 496. For instance, the identifying, the determining, and the deploying, and other steps described herein may occur in real-time, ongoing, or on-the fly. As an example, one or more steps described herein may be performed on-the-fly (e.g., the chassis management module may detect a change in the relationships between the plurality of physical servers and the plurality of physical cooling fans, and redetermine/reconfigure the placement arrangement based on the updated relationships to facilitate cooling efficiency for the plurality of physical servers) in order to streamline (e.g., facilitate, promote, enhance) asset placement management.

Method 400 concludes at block 499. Aspects of method 400 may provide performance or efficiency benefits for asset placement management. For example, aspects of method 400 may have positive impacts with respect to managing asset placement in a shared pool of configurable computing resources having a plurality of physical servers and a plurality of physical cooling fans. As an example, asset placement arrangements to leverage the configuration of cooling fans in a particular server chassis may be determined to facilitate thermal management for a set of servers. Altogether, leveraging cooling fan arrangement/configuration information for asset deployment may be associated with power consumption efficiency, asset performance, and component longevity

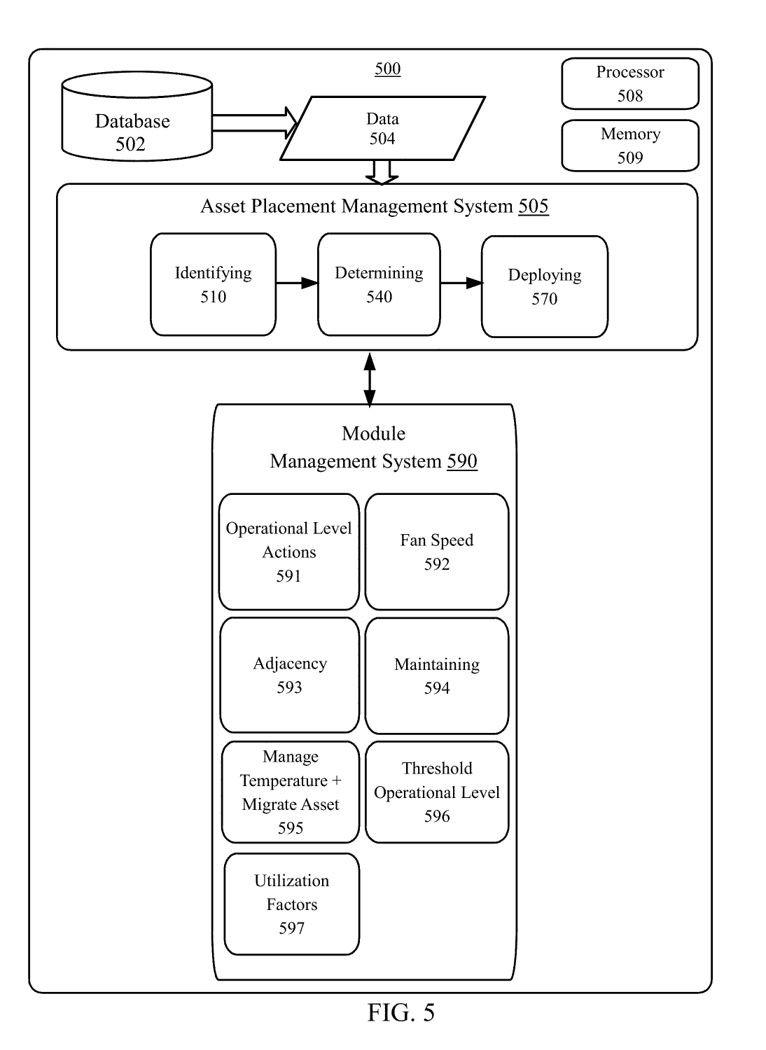

FIG. 5 shows an example system 500 for asset placement management in a shared pool of configurable computing resources having both a plurality of physical servers and a plurality of physical cooling fans, according to embodiments. The example system 500 may include a processor 508 and a memory 509 to facilitate implementation of asset placement management techniques. The example system 500 may include a database 502 (e.g., chassis management database, physical and logical topology map). In embodiments, the example system 500 may include an asset placement management system 505. The asset placement management system 505 may be communicatively connected to the database 502, and be configured to receive data 504 (e.g., asset placement requests) related to asset placement management. The asset placement management system 505 may include an identifying module 510 to identify a set of relationships with respect to the plurality of physical servers and the plurality of physical cooling fans, a determining module 540 to determine a placement arrangement for the set of assets with respect to the plurality of physical servers, and a deploying module 570 to deploy the set of assets based on the placement arrangement. The asset placement management system 505 may be communicatively connected with a module management system 590 that includes one or more modules for implementing aspects of asset placement management. Aspects of example system 500 may be similar or the same as aspects of method 400, and aspects may be utilized interchangeably with one or more methodologies described herein.

In embodiments, operational level actions may occur at module 591. Aspects of the disclosure relate to the recognition that, in embodiments, the operational level (e.g., degree, intensity, or extent of utilization) of physical cooling fans may be used to influence asset deployment. A particular asset may be received (e.g., detected, sensed, collected, identified, delivered) for deployment to the plurality of physical servers. The particular asset may include a workload, virtual machine, logical partition, application program, or other type of asset scheduled for allocation to the plurality of physical servers. A first operational level of the first physical cooling fan may be detected (e.g., sensed, recognized, discovered, identified, ascertained, determined). The operational level may be expressed as a number of rotations per minute (e.g., 2500 RPM), a percentage of utilization (e.g., 75%), a voltage level (e.g., 12 Volts), or the like. For instance, the first operational level of the first physical cooling fan may be detected to be 3400 RPM. A second operational level of the second physical cooling fan may be detected. As an example, the second operational level of the physical cooling fan may be detected to be 2100 RPM. The first and second operational levels may be compared (e.g., contrasted, assessed, juxtaposed, evaluated). For instance, comparing may include examining the magnitude of the first operational level of 3400 RPM with respect to the second operational level of 2100 RPM. A determination may be made that the first operational level exceeds the second operational level. For instance, in response to examining the magnitude of the first and second operational levels with respect to each other, it may be ascertained that the first operational level of 3400 RPM exceeds (e.g., is greater than or equal to, surpasses) the second operational level of 2100 RPM. The particular asset may be deployed (e.g., placed, distributed, assigned, allocated) to the first group of physical servers. This deployment may occur in response to determining that the first operational level exceeds the second operational level. For instance, the hypervisor may be configured to install the particular asset on the first group of physical servers. In this way, the particular asset may leverage the greater operational level of the first group of servers for cooling efficiency. Other methods of operational level actions are also possible.

In embodiments, the asset placement management system may detect that the second physical cooling fan indicates a speed of zero at module 592. Generally, detecting can include recognizing, sensing, discovering, ascertaining, or otherwise determining that the second physical cooling fan indicates a speed of zero. In embodiments, the speed of zero may indicate a number of revolutions per minute of zero (e.g., 0 PM). In embodiments, the speed of zero may indicate that the second physical cooling fan is off, inactive, disabled, idle, or the like. As described herein, aspects of the disclosure relate to limiting (e.g., avoiding, preventing) placement of assets on inactive fans (e.g., to promote cooling efficiency by leveraging already-active cooling fans). Accordingly, as described herein, when determining the placement arrangement, physical servers associated with active (e.g., speed of non-zero) cooling fans may be prioritized for receiving deployment of a set of assets. For example, in response to comparing a first operational level of a first cooling fan of 1800 RPM and a second operational level of a second cooling fan of 0 RPM, one or more physical servers associated with the first cooling fan may be selected to receive placement of a set of assets. In embodiments, detecting may include using a fan controller (e.g., managed by a service processor, chassis management module) to ascertain the operational level of one or more cooling fans located in a server chassis. Other methods of detecting that the second physical cooling fan indicates a speed of zero are also possible.

In embodiments, the asset placement management system may include a first physical server that is adjacent to a second physical server at module 593. Aspects of the disclosure relate to the recognition that, in some situations, placing assets on adjacent physical servers may promote cooling efficiency (e.g., multiple servers may share the same cooling fan, avoiding the need to turn on another cooling fan). In embodiments, the first physical server and the second physical server may be cooled by the same physical cooling fan. In embodiments, the first physical server and the second physical server may be cooled by separate cooling fans. A specific asset may be sensed (e.g., detected, ascertained) at the first physical server. The specific asset may include a workload, application program, logical partition, or virtual machine hosted by the first physical server. The particular asset may be selected (e.g., chosen, elected, picked, identified, determined) for deployment to an adjacent physical server. The adjacent physical server may include a physical server that is neighboring, bordering, adjoining, above/below, next-to, side-to-side with, diagonal from, alongside, or beside the first physical server. This deployment may occur in response to sensing that the first physical server has the specific asset. The specific asset may be deployed (e.g., placed, distributed, allocated, migrated, transferred) to the second physical server. For instance, the hypervisor may install the specific asset on the second physical server. In this way, both the first and second physical servers may leverage active fans (e.g., the same cooling fan or nearby cooling fans) for cooling. Other methods of deploying the specific and particular assets are also possible.

In embodiments, the asset placement management system may maintain the first and second operational levels at module 594. Generally, maintaining can include preserving, sustaining, keeping, continuing, or otherwise retaining the first and second operational levels. In embodiments, maintaining the first and second operational levels may include setting the first and second operational levels to a fixed value. For instance, the fan speed (e.g., number of rotations per minute), voltage, or relative utilization of the cooling fan may be locked to a particular value, and maintained at the particular value even in the event of asset migration, deployment, rearrangement, or other workload or physical/logical topology changes. As examples, maintaining may include setting the first and second operational levels to a fixed speed of 2400 RPM, a fixed utilization of 85%, a fixed voltage of 14.5 Volts, or the like. In certain embodiments, maintaining may include refraining (e.g., preventing, denying, avoiding) from turning on a cooling fan that is currently off or inactive. Other methods of maintaining the first and second operation levels are also possible.

In embodiments, the temperature of a hardware device having the set of assets may be managed (e.g., controlled, regulated, adjusted, modified) at module 595. In certain embodiments, managing the temperature may include configuring the operational parameters of an asset or workload hosted by a physical server (e.g., to adjust the intensity of the workload and the heat generated by the host hardware device). A specific asset may be migrated to an adjacent physical server. Generally, migrating can include transferring, placing, allocating, assigning, moving, or otherwise relocating the specific asset. The adjacent physical server may be cooled by the same physical cooling fan as the hardware device that originally hosted the specific asset. This may be performed without changing an operational level of the same physical cooling fan. Consider the following example. A first physical server may host a set of assets, and have an operating temperature of 45° C. The first physical server may be cooled by a cooling fan operating at 4000 RPM. As described herein, a specific asset of the set of assets may be migrated to a second physical server that is adjacent to the first physical server and shares the same physical cooling fan. As a result of moving the specific asset, the operating temperature of the first physical server may decrease (e.g., from 45° C. to 40° C.) without the need for activation of another physical cooling fan. Other methods of managing the temperature of a hardware device by migrating assets are also possible.

In embodiments, a set of operations related to threshold operational levels may be performed at module 596. The asset placement management system may sense (e.g., detect, recognize, ascertain, determine) that the first group of physical servers has a specific asset (e.g., workload, application program, virtual machine, logical partition). For example, the asset placement management system may sense that the first group of physical servers hosts a specific asset including an enterprise management application. The first operational level (e.g., degree, intensity, extent of utilization) of the first physical cooling fan may be detected. In embodiments, the first operational level may be detected using a fan controller managed by a chassis management module. For instance, the first operational level of the first physical cooling fan may be detected to be 90% (e.g., the first physical cooling fan is running at 90% of its maximum speed/capacity). The first operational level may be compared (e.g., contrasted, assessed, evaluated) with a threshold operational level. The threshold operational level may include a benchmark, criterion, or reference operational level. In embodiments, the threshold operational level may indicate a recommended operational level (e.g., maximum safe level of operation). For example, the threshold operational level for the first physical cooling fan may be 75%. Accordingly, the first operational level of 90% may be examined with respect to the threshold operational level of 75%. The first operational level may be determined (e.g., ascertained, identified) to exceed the threshold operational level. For instance, in response to comparing the first operational level with the threshold operational level, it may be determined that the first operational level of 90% exceeds (e.g., surpasses) the threshold operational level of 75%. The specific asset may be migrated (e.g., transferred, moved, allocated) to the second group of physical servers. This migration may occur in response to determining that the first operational level exceeds the threshold operational level. Accordingly, in certain embodiments, migrating the specific asset to another group of physical servers may positively impact the first operational level of the first physical cooling fan. For instance, in response to migrating the specific asset, the first operational level may decrease from 90% to 72% (e.g., below the threshold operational level). In certain embodiments, in the event that the first operational level does not fall below the threshold operational level after migration of the specific asset, other assets may be relocated until the first operational level achieves (e.g., falls below) the threshold operational level. Other methods of performing operations related to threshold operational levels are also possible.

In embodiments, a set of operations related to utilization factors may be performed at module 597. Aspects of the present disclosure relate to providing recommended candidate server arrangements to facilitate cooling efficiency and asset performance. The asset placement management system may ascertain (e.g., identify, calculate, compute, formulate, determine) a first utilization factor. This first utilization factor may be ascertained for the first group of physical servers. The first utilization factor may include an indication of the degree, intensity, or extent to which one or more physical servers of the first group of physical servers are utilized. For instance, the first utilization factor may indicate the relative portion of the system resources (e.g., processor, memory, storage) of a physical server that are in use (e.g., for processing/handling/running an asset or workload). As an example, the first utilization factor may be ascertained to be 82% (e.g., the first group of physical servers are being utilized as 82% of their maximum resource-allowed capacity). The asset placement management system may ascertain a second utilization factor for the second group of physical servers. For instance, the second utilization factor may be ascertained to be 91%. The first and second utilization factors may be compared (e.g., contrasted, evaluated, assessed, examined) with a threshold utilization factor. The threshold utilization factor may include a benchmark, criterion, or reference level of utilization. In embodiments, the threshold utilization factor may indicate a recommended level of utilization. As an example, the threshold utilization factor may include a value of 80%. The first and second utilization factors may be determined (e.g., identified, ascertained) to exceed the threshold utilization factor. For instance, the first utilization factor of 82% and the second utilization factor of 91% may be compared to the threshold utilization factor of 80%, and it may be ascertained that the magnitude of both the first and second utilization factors surpasses the threshold utilization factor. A candidate server arrangement may be resolved (e.g., formulated, computed, derived, ascertained, determined) to use a common physical cooling fan. This common physical cooling fan may be configured and arranged to cool at least a portion of both the first and second groups of physical servers. The candidate server arrangement may include a potential (e.g., recommended) physical or logical configuration of the first and second group of servers that promotes cooling efficiency and asset performance. For instance, the candidate server arrangement may indicate a recommended slot for placement of a particular physical server (e.g., such that the physical server may benefit from cooling of an active cooling fan). As an example, the candidate server arrangement may indicate that if a first physical server from the first group is moved to a first server slot, and the second physical server from the second group is moved to a second server slot, both physical servers may leverage a common physical cooling fan (e.g., resulting in lower temperatures, component longevity, and asset performance.) The candidate server arrangement may be provided. Generally, providing can include conveying, displaying, relaying, demonstrating, exhibiting, or otherwise presenting the candidate server arrangement. In embodiments, providing may include indicating the candidate server arrangement to a user or administrator. For instance, the hypervisor or chassis management module may be configured to display a dialogue message in a user interface that presents the candidate server arrangement. Other methods of performing a set of operations related to utilization factors are also possible.

In addition to embodiments described above, other embodiments having fewer operational steps, more operational steps, or different operational steps are contemplated. Also, some embodiments may perform some or all of the above operational steps in a different order. In embodiments, operational steps may be performed in response to other operational steps. The modules are listed and described illustratively according to an embodiment and are not meant to indicate necessity of a particular module or exclusivity of other potential modules (or functions/purposes as applied to a specific module).

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

Embodiments according to this disclosure may be provided to end-users through a cloud-computing infrastructure. Cloud computing generally refers to the provision of scalable computing resources as a service over a network. More formally, cloud computing may be defined as a computing capability that provides an abstraction between the computing resource and its underlying technical architecture (e.g., servers, storage, networks), enabling convenient, on-demand network access to a shared pool of configurable computing resources that can be rapidly provisioned and released with minimal management effort or service provider interaction. Thus, cloud computing allows a user to access virtual computing resources (e.g., storage, data, applications, and even complete virtualized computing systems) in “the cloud,” without regard for the underlying physical systems (or locations of those systems) used to provide the computing resources.

Typically, cloud-computing resources are provided to a user on a pay-per-use basis, where users are charged only for the computing resources actually used (e.g., an amount of storage space used by a user or a number of virtualized systems instantiated by the user). A user can access any of the resources that reside in the cloud at any time, and from anywhere across the Internet. In context of the present disclosure, a user may access applications or related data available in the cloud. For example, the nodes used to create a stream computing application may be virtual machines hosted by a cloud service provider. Doing so allows a user to access this information from any computing system attached to a network connected to the cloud (e.g., the Internet).

Embodiments of the present disclosure may also be delivered as part of a service engagement with a client corporation, nonprofit organization, government entity, internal organizational structure, or the like. These embodiments may include configuring a computer system to perform, and deploying software, hardware, and web services that implement, some or all of the methods described herein. These embodiments may also include analyzing the client's operations, creating recommendations responsive to the analysis, building systems that implement portions of the recommendations, integrating the systems into existing processes and infrastructure, metering use of the systems, allocating expenses to users of the systems, and billing for use of the systems.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to exemplary embodiments, other and further embodiments of the invention may be devised without departing from the basic scope thereof, and the scope thereof is determined by the claims that follow. The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. “Set of,” “group of,” “bunch of,” etc. are intended to include one or more. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of exemplary embodiments of the various embodiments, reference was made to the accompanying drawings (where like numbers represent like elements), which form a part hereof, and in which is shown by way of illustration specific exemplary embodiments in which the various embodiments may be practiced. These embodiments were described in sufficient detail to enable those skilled in the art to practice the embodiments, but other embodiments may be used and logical, mechanical, electrical, and other changes may be made without departing from the scope of the various embodiments. In the previous description, numerous specific details were set forth to provide a thorough understanding the various embodiments. But, the various embodiments may be practiced without these specific details. In other instances, well-known circuits, structures, and techniques have not been shown in detail in order not to obscure embodiments.

What is claimed is:

1. A computer-implemented method for asset placement management in a shared pool of configurable computing resources having both a plurality of physical servers and a plurality of physical cooling fans, the method comprising:
identifying, with respect to the plurality of physical servers and the plurality of physical cooling fans, a set of relationships which indicates:
a first physical cooling fan is configured and arranged to cool a first group of physical servers, and
a second physical cooling fan is configured and arranged to cool a second group of physical servers;
determining, based on the set of relationships, a placement arrangement for a set of assets with respect to the plurality of physical servers; and
deploying, based on the placement arrangement, the set of assets.

2. The method of claim 1, wherein the first and second groups of physical servers are mutually exclusive.

3. The method of claim 1, wherein the plurality of physical servers are embedded in a single physical chassis.

4. The method of claim 1, wherein a single hypervisor manages the plurality of physical servers.

5. The method of claim 1, further comprising:
mapping that the first physical cooling fan is configured and arranged to cool the first group of physical servers; and
mapping that the second physical cooling fan is configured and arranged to cool the second group of physical servers.

6. The method of claim 1, further comprising:
receiving a particular asset for deployment to the plurality of physical servers;
detecting a first operational level of the first physical cooling fan;
detecting a second operational level of the second physical cooling fan;
comparing the first and second operational levels;
determining that the first operational level exceeds the second operational level; and
deploying, in response to determining that the first operational level exceeds the second operational level, the particular asset to the first group of physical servers.

7. The method of claim 6, further comprising:
detecting that the second physical cooling fan indicates a speed of zero.

8. The method of claim 6, wherein first group of physical servers includes a first physical server that is adjacent to a second physical server, further comprising:
sensing that the first physical server has a specific asset;
selecting, in response to sensing that the first physical server has the specific asset, to deploy the particular asset to an adjacent physical server; and
deploying the particular asset to the second physical server.

9. The method of claim 8, further comprising:
maintaining the first and second operational levels.

10. The method of claim 1, further comprising:
managing a temperature of a hardware device having the set of assets; and
migrating a specific asset to an adjacent physical server cooled by a same physical cooling fan without changing an operational level of the same physical cooling fan.

11. The method of claim 1, further comprising:
sensing that the first group of physical servers has a specific asset;
detecting a first operational level of the first physical cooling fan;
comparing the first operational level with a threshold operational level;
determining that the first operational level exceeds the threshold operational level; and
migrating, in response to determining that the first operational level exceeds the threshold operational level, the specific asset to the second group of physical servers.

12. The method of claim 1, further comprising:
ascertaining, for the first group of physical servers, a first utilization factor;
ascertaining, for the second group of physical servers, a second utilization factor;
comparing both the first and second utilization factors with a threshold utilization factor;
determining that both the first and second utilization factors exceed the threshold utilization factor;
resolving a candidate server arrangement to use a common physical cooling fan to be configured and arranged to cool at least a portion of both the first and second groups of physical servers; and
providing the candidate server arrangement.

13. The method of claim 1, wherein the set of assets is selected from the group consisting of: one or more application programs, one or more workloads, one or more virtual machines, and one or more logical partitions.

14. The method of claim 1, wherein both the first group of physical servers and the first physical cooling fan are located in a first geographic location, wherein both the second group of physical servers and the second physical cooling fan are located in a second geographic location, and wherein a threshold distance separates the first and second geographic locations.

15. The method of claim 1, wherein the identifying, the determining, and the deploying each occur in a dynamic fashion to streamline asset placement management.

16. The method of claim 1, wherein the identifying, the determining, and the deploying each occur in an automated fashion without user intervention.

17. The method of claim 1, wherein the first and second groups of physical servers are mutually exclusive, wherein a single hypervisor manages the plurality of physical servers, further comprising:
mapping that the first physical cooling fan is configured and arranged to cool the first group of physical servers;
mapping that the second physical cooling fan is configured and arranged to cool the second group of physical servers;
receiving a particular asset for deployment to the plurality of physical servers;
detecting a first operational speed of the first physical cooling fan;
detecting a second operational speed of the second physical cooling fan;
comparing the first and second operational speeds;
determining that the first operational speed exceeds the second operational speed; and
deploying, in response to determining that the first operational speed exceeds the second operational speed, the particular asset to the first group of physical servers.

18. A system for asset placement management in a shared pool of configurable computing resources having both a plurality of physical servers and a plurality of physical cooling fans, the system comprising:
a memory having a set of computer readable computer instructions, and a processor for executing the set of computer readable instructions, the set of computer readable instructions including:
identifying, with respect to the plurality of physical servers and the plurality of physical cooling fans, a set of relationships which indicates:
a first physical cooling fan is configured and arranged to cool a first group of physical servers, and
a second physical cooling fan is configured and arranged to cool a second group of physical servers;
determining, based on the set of relationships, a placement arrangement for a set of assets with respect to the plurality of physical servers; and
deploying, based on the placement arrangement, the set of assets.

19. A computer program product for asset placement management in a shared pool of configurable computing resources having both a plurality of physical servers and a plurality of physical cooling fans, the computer program product comprising a computer readable storage medium having program instructions embodied therewith, wherein the computer readable storage medium is not a transitory signal per se, the program instructions executable by a processor to cause the processor to perform a method comprising:
identifying, with respect to the plurality of physical servers and the plurality of physical cooling fans, a set of relationships which indicates:
a first physical cooling fan is configured and arranged to cool a first group of physical servers, and
a second physical cooling fan is configured and arranged to cool a second group of physical servers;
determining, based on the set of relationships, a placement arrangement for a set of assets with respect to the plurality of physical servers; and
deploying, based on the placement arrangement, the set of assets.

20. The computer program product of claim 19, wherein at least one of:
the program instructions are stored in the computer readable storage medium in a data processing system, and wherein the program instructions were downloaded over a network from a remote data processing system; or
the program instructions are stored in the computer readable storage medium in a server data processing system, and wherein the program instructions are downloaded over a network to the remote data processing system for use in a second computer readable storage medium with the remote data processing system.
